(19) United States
(12) Patent Application Publication
(10) Pub. No.: US 2008/0029910 A1
(43) Pub. Date: Feb. 7, 2008

(54) LAYOUT OF ARRAY OF ELECTRICAL INTERCONNECT TO INCREASE I/O DENSITY PACKAGING

(76) Inventors: David L. Edwards, Poughkeepsie, NY (US); Thomas J. Fleischman, Poughkeepsie, NY (US)

Correspondence Address: HOFFMAN, WARNICK & D'ALESSANDRO LLC, 75 STATE ST, 14TH FL, ALBANY, NY, 12207, US

(21) Appl. No.: 11/461,869

(22) Filed: Aug. 2, 2006

(51) Int. Cl. H01L 23/48

(52) U.S. Cl. 257/786

(57) ABSTRACT

An embodiment of the present invention discloses a hexagonally structured electrical interconnect connector and a layout arrangement for a plurality of the same on a chip carrier or a multi-chip module (MCM) in a hexagonal array to increase the input output (I/O) density. The hexagonal electrical interconnect connector may take the form of a pad, ball or pin; and is adjacent to another hexagonal electrical interconnect connector at angle, θ.

### BACKGROUND OF THE INVENTION

1. Technical Field

The invention relates generally to a layout structure of electrical interconnect connectors in an integrated circuit (IC) chip carrier or multi-chip module (MCM). Particularly, to a layout structure where neighboring electrical interconnect connectors are linearly spaced at an angle from the respective center of each pad.

2. Background Art

As the size of electronic devices shrink while demand for performance increase, constant efforts are made to increase input/output (I/O) density of IC chip carriers. The I/O density of an array of electrical interconnect connectors (i.e., pads/pins/balls) on IC chip carriers has an influence on the packing cost which varies with the number of devices that can be connected to the IC chip carrier. The diminishing critical dimensions (CD) in IC chips afford an increase in packing density onto chip carriers having increased I/O densities.

As shown in FIG. 1, electrical interconnect pads 12′, 12″, 12′″ are arranged in a rectilinear array 10 on a chip carrier 14. A conventional array is square where adjacent electrical interconnect pads 12′, 12″ and 12′″ form a center-to-center angle, θ₁=90°. Square arrays usually provide I/O features of constant pitch 16 and spacing 16′. Increasing the I/O density for this typical array requires a reduction in the pitch and/or feature size 16″ and consequently the spacing 16′ between adjacent electrical interconnect pads 12′, 12″, 12′″. This may require new technologies to ensure flatter, cleaner surfaces on chip carriers for tighter alignment accuracy and to maintain acceptable levels of manufacturability and reliability.

Another manner of increasing the I/O density, as shown in FIG. 2, is to have electrical interconnect pads 22′, 22″, 22′″ arranged in a hexagonal array 20. In hexagonal array 20, electrical interconnect pad 22″ is arranged with an angle, θ₂=approximately 60° center-to-center separation from adjacent electrical interconnect pads 22′ and 22′″. The I/O density in such an arrangement is higher by approximately 15% than the conventional square array 10 with the same feature size, spacing and pitch between adjacent pads. This allows more electrical interconnect pads on the surface of the chip carrier 24 while maintaining the same pad-to-pad pitch 26 as in the square array 16 (i.e. 90° center-to-center array) (FIG. 1). The advantage of a hexagonal array arrangement provides a higher I/O density as demonstrated by achieving a higher number of interconnect pad or ball in a same area.

In view of the foregoing, there is a need in the art for a solution to the problems of the related art.

### SUMMARY OF THE INVENTION

An embodiment of the present invention discloses a hexagonally structured electrical interconnect connector and a layout arrangement for a plurality of the same on a chip carrier or a multi-chip module (MCM) in a hexagonal array to increase the input output (I/O) density. The hexagonal electrical interconnect connector may take the form of a pad, ball or pin; and is adjacent to another hexagonal electrical interconnect connector at angle, θ.

One aspect of the present invention includes a layout of an array for a chip carrier, the layout comprising: a plurality of electrical interconnect connectors arranged in a hexagonal array, wherein each adjacent electrical interconnect connector has a center-to-center acute angle, θ, separation; and wherein each of the plurality electrical interconnect connector is hexagonally shaped.

The illustrative aspects of the present invention are designed to solve the problems herein described and other problems not discussed which are discoverable by a skilled artisan.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 is a plan view of a typical array of conventional electrical interconnect pads on a chip carrier.

FIG. 2 is a plan view of another array of conventional electrical interconnect pads on a chip carrier.

FIG. 3 is a plan view of an array according to an embodiment of the present invention.

FIG. 4(a)-4(c) is a plan view of various shapes and sizes of pads in different embodiments of the present invention.

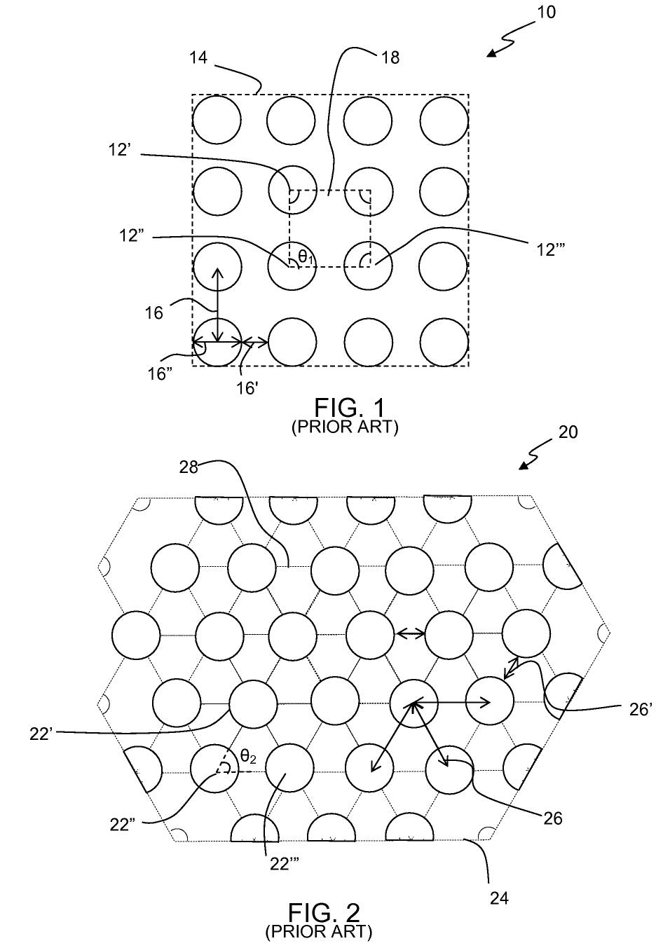

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

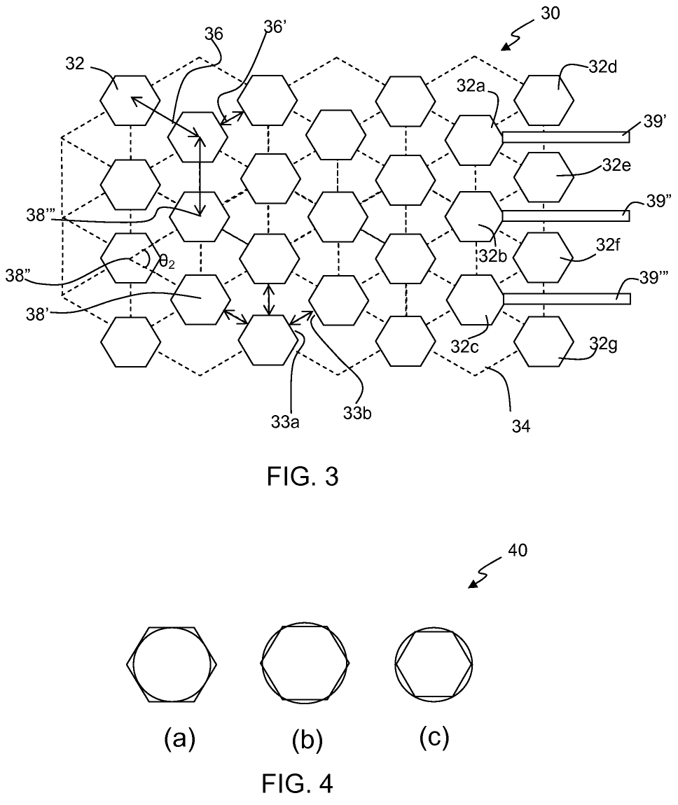

FIG. 3 illustrates an electrical interconnect array 30 on a carrier 34 according to an embodiment of the present invention. The electrical interconnect array 30 is a substantially hexagonal array. On a surface of carrier 34 is printed multiple electrical interconnect connectors 32. Each electrical interconnect connector 32 is substantially hexagonally shaped. Substantial hexagonal electrical interconnect connectors 32 (hereafter simply referred to as “hexagonal pads”) are arranged in an array such that each hexagonal pad relates to any two adjacent hexagonal pads at a center-to-center angle, θ₂. In one embodiment θ₂ is approximately 60°. The angle, θ₂ is suspended from the center of a hexagonal pad 32. For example, in FIG. 3, hexagonal pad with center 38″ relates to hexagonal pad having center 38′ and hexagonal pad having center 38′″ such that an angle θ₂=approximately 60° is suspended at center 38″. Feature pitch 36 in this array is maintained as in the hexagonal array with conventional round electrical interconnect pads. For the carrier 34 to accommodate a module, for example a multi-chip module (MCM), that is connected to, for example, a circuit board or a card, feature pitch 36 may range from approximately 0.5 mm to approximately 1.5 mm. Whereas for carrier 34 to accommodate a chip that is connected to a module, feature pitch 36 may range from approximately 0.1 mm to approximately 0.3 mm. Additionally, the spacing between any adjacent hexagonal pads 32 are of equidistance 36′. In accommodating a module or a chip, the spacing between adjacent hexagonal pads may range from approximately 10% of feature pitch 36 to approximately 50% of feature pitch 36. In addition to retaining the 15% packing density in a hexagonal array, hexagonal pads 32 facilitate higher packing density without compromising spacing 36′.

The following paragraphs discuss the comparative studies of different embodiments of the present invention with reference to conventional round shaped electrical interconnect pads illustrating the difference in packing density.

Implementation of the invention can take the form of any one of the embodiments illustrated in FIG. 4(a)-4(c), but not limited to only these embodiments.

FIG. 4(a) illustrates a hexagonal pad with a conventional round electrical interconnect pad (hereafter simply referred to as round pad) inscribed therein. Results from a comparison study set out in Table 1(a) shows that the hexagonal pad is approximately 10% greater in area than the conventional round pad.

TABLE 1(a)
Case A - Round Pad Inscribed in Hex Pad (same pad-to-pad
spacing)

| | | | | | |
|---|---|---|---|---|---|
| Pad Pitch | 1.00 | 1.00 | 1.00 | 1.00 | 1.00 |
| Factor | 50% | 60.0% | 70.0% | 80.0% | 90.0% |
| Round Pad Size | 0.50 | 0.60 | 0.70 | 0.80 | 0.90 |
| Round Pad (Area) | 0.196 | 0.283 | 0.385 | 0.503 | 0.636 |
| Round Pad (Spacing) | 0.50 | 0.40 | 0.30 | 0.20 | 0.10 |
| Hex Pad (Area) | 0.217 | 0.312 | 0.424 | 0.554 | 0.701 |
| Hex Pad (Spacing) | 0.50 | 0.40 | 0.30 | 0.20 | 0.10 |
| Hex Pad Spacing | 0.0% | 0.0% | 0.0% | 0.0% | 0.0% |
| Increase | | | | | |
| Hex Pad Area Increase | 10.3% | 10.3% | 10.3% | 10.3% | 10.3% |

For example, the round pad area at round pad spacing of approximately 0.50 nm is approximately 0.196 nm² while the hexagonal pad area at hexagonal pad spacing of approximately 0.50 mm is approximately 0.217 mm². This difference in area is approximately 10%. As the pad spacing decreases from approximately 0.50 nm to approximately 0.10 nm, the additional area from hexagonal pads remain at approximately 10% greater than conventional round pads. With a greater area, the electrical contact surface is increased which improves the connectivity of devices to chip carrier 34 (in FIG. 3).

FIG. 4(b) illustrates a hexagonal pad with conventional round pad where the total area of both pads is the same. The result of a comparative study between the two types of pad is shown in Table 1(b).

TABLE 1(b)
Case B - Hex Pad of Same Area as Round Pad

| | | | | | |
|---|---|---|---|---|---|
| Pad Pitch | 1.00 | 1.00 | 1.00 | 1.00 | 1.00 |
| Factor | 50% | 60.0% | 70.0% | 80.0% | 90.0% |
| Round Pad Size | 0.50 | 0.60 | 0.70 | 0.80 | 0.90 |
| Round Pad (Area) | 0.196 | 0.283 | 0.385 | 0.503 | 0.636 |
| Round Pad (Spacing) | 0.50 | 0.40 | 0.30 | 0.20 | 0.10 |
| Hex Pad (Area) | 0.196 | 0.283 | 0.385 | 0.503 | 0.636 |
| Triangle Height | 0.238 | 0.286 | 0.333 | 0.381 | 0.429 |
| Hex Pad (Spacing) | 0.524 | 0.429 | 0.333 | 0.238 | 0.143 |
| Hex Pad Spacing Increase | 4.8% | 7.2% | 11.1% | 19.1% | 42.9% |
| Hex Pad Area Increase | 0.0% | 0.0% | 0.0% | 0.0% | 0.0% |

From Table 1(b), where the area of the hexagonal pads are comparably constant with the area of conventional round pads, the spacing between the hexagonal pads is comparatively greater than the spacing of conventional round pads. For example, at pad area of approximately 0.196 mm², the spacing between conventional round pads is approximately 0.50 mm while hexagonal pads of the same area have a spacing of approximately 0.524 mm. The result also shows that the percentage increase in spacing between hexagonal pads increases as the spacing becomes smaller. For example, at a pad area of approximately 0.196 mm², where round pad spacing is approximately 0.50 mm and where the spacing between hexagonal pads is approximately 0.524 mm, the percentage increase in the spacing comparing hexagonal pads to conventional round pads is approximately 4.8%. At the area of approximately 0.63 mm², where the spacing between hexagonally shaped pads is approximately 0.143 mm and the spacing of round shaped conventional pads is approximately 0.10 mm, the percentage increase in spacing of hexagonal pads as compared to round pads is at approximately 42.9%. The trend shown in Table 1(b) suggests that hexagonally shaped pads can be packed in an array at a higher density than round shaped conventional pads.

FIG. 4(c) illustrates an embodiment where a hexagonal pad is inscribed in a conventional round pad.

TABLE 1(c)
Case C - Hex Pad Inscribed in Round Pad

| | | | | | |
|---|---|---|---|---|---|
| Pad Pitch | 1.00 | 1.00 | 1.00 | 1.00 | 1.00 |
| Factor | 50.0% | 60.0% | 70.0% | 80.0% | 90.0% |
| Round Pad Size | 0.50 | 0.60 | 0.70 | 0.80 | 0.90 |
| Round Pad (Area) (mm²) | 0.196 | 0.283 | 0.385 | 0.503 | 0.636 |
| Round Pad (Spacing) (mm) | 0.50 | 0.40 | 0.30 | 0.20 | 0.10 |
| Triangle Height | 0.217 | 0.260 | 0.303 | 0.346 | 0.390 |
| Hex Pad (Area) (mm²) | 0.162 | 0.234 | 0.318 | 0.416 | 0.526 |
| Hex Pad (Spacing) (mm) | 0.567 | 0.480 | 0.394 | 0.307 | 0.221 |
| Hex Pad Spacing Increase | 13.4% | 20.1% | 31.3% | 53.6% | 120.6% |
| Hex Pad Area Increase | −17.3% | −17.3% | −17.3% | −17.3% | −17.3% |

Table 1(c) shows the results of a comparative study of the characteristics of the two types of pads. The hexagonal pad has a smaller area than the conventional round pad by a percentage of approximately 17.3%. The smaller area affords greater spacing between the hexagonal pads. For example, comparing hexagonal pad of area at approximately 0.162 mm² and round pad area at approximately 0.196 mm², the spacing between round pads is approximately 0.50 mm while the spacing between hexagonal pads is approximately 0.567 mm. This comparative increase in spacing progresses with increase in hexagonal pad area. For example, comparing a hexagonal pad with an area of approximately 0.162 mm² to a hexagonal pad with an area of approximately 0.526 mm², the percentage increase in spacing is from approximately 13.4% to approximately 120.6%. This indicates that a slight decrease in pad area will produce a significantly larger spacing between pads. This increased spacing reduces the risk of shorting between pads, or can be used for surface wiring as compared to the use of conventional round pads.

Returning to FIG. 3, in addition to retaining the packing density of conventional hexagonal array achieved with conventional round pads, the hexagonal pads provides a further packing advantage by enabling line features 39′, 39″ and 39′″ to be incorporated between the hexagonal electrical interconnect pads 32. FIG. 3 shows line feature 39′ extending from pad 32a through spacing between pads 32d and 32e, line feature 39″ extending from pad 32b through spacing between pads 32e and 32f and line feature extending from pad 32c through the spacing between pad 32f and 32g. Such an arrangement is made possible by having adjacent hexagonal pads 32 arranged in substantially hexagonal electrical interconnect array 30 with facing edges 33a, 33b of adjacent hexagonal pads parallel to each other forming parallel features.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A layout for an array of a chip carrier, the layout comprising:
a plurality of electrical interconnect connectors arranged in a hexagonal array,
wherein each adjacent electrical interconnect connector has a center-to-center acute angle, θ, separation; and
wherein each of the plurality of electrical interconnect connectors are substantially hexagonally shaped.

2. The layout of claim 2, wherein the center-to-center acute angle is approximately 60°.

3. The layout of claim 1, further comprising a feature pitch for a module, wherein the feature pitch ranges from approximately 0.5 mm to approximately 1.5 mm.

4. The layout of claim 1, further comprising a feature pitch for a chip, wherein the feature pitch ranges from approximately 0.1 mm to approximately 0.3 mm.

5. The layout of claim 1, wherein each adjacent electrical interconnect has a spacing ranging from approximately 10% to approximately 50% of a feature pitch of a module.

6. The layout of claim 1, wherein adjacent electrical interconnect connectors have a spacing ranging from approximately 10% to approximately 50% of feature pitch of a chip.

7. The layout of claim 1, wherein a line feature is incorporated between adjacent electrical interconnect connectors.

8. The layout of claim 1, wherein the adjacent electrical interconnect connectors have edges that are substantially parallel.
